(19) United States
(12) Patent Application Publication
(10) Pub. No.: US 2026/0082657 A1
(43) Pub. Date: Mar. 19, 2026

(54) VERTICAL TRANSISTOR DEVICE AND METHOD OF FABRICATING A VERTICAL TRANSISTOR DEVICE

(71) Applicant: Infineon Technologies Austria AG, Villach (AT)

(72) Inventor: Christian Ranacher, Gaimberg (AT)

(21) Appl. No.: 19/300,922

(22) Filed: Aug. 15, 2025

(30) Foreign Application Priority Data
Sep. 18, 2024 (DE) 102024208900.1

(51) Int. Cl. H10D 64/00; H10D 30/01; H10D 30/66; H10D 62/10; H10D 64/66; H10D 84/01; H10D 84/83

(52) U.S. Cl. CPC H10D 64/117; H10D 30/0297; H10D 30/668; H10D 62/107; H10D 84/016; H10D 84/839; H10D 64/661

(57) ABSTRACT

In an embodiment, a vertical transistor device includes a semiconductor substrate having a first major surface and a second major surface opposing the first major surface. At least one transistor cell formed in the semiconductor substrate includes a fin having an upper surface and side walls. The fin includes a source region, a body region and a drift zone that are located along a length of the fin. The body region extends between the source region and the drift zone. The transistor cell further includes a gate arranged on the upper surface and the side walls of the fin. A source pad is located on the first major surface and a drain pad is located on the second major surface of the semiconductor substrate.

### BACKGROUND

Transistors used in power electronic applications may be fabricated with silicon (Si) semiconductor materials. Common transistor devices for power applications include Si superjunction MOSFETs, e.g. CoolMOS™, Si Power MOSFETs, e.g. split gate MOSFETs, and Si Insulated Gate Bipolar Transistors (IGBTs). The transistor devices may be used in circuits such as half-bridge or full-bridge circuits.

It is desirable that transistor devices for power applications have a low on resistance (Ron) and a high blocking capability in order to increase the efficiency and performance of the circuit in which they are used.

### SUMMARY

According to an embodiment, a vertical transistor device is provided that comprises a semiconductor substrate comprising a first major surface, a second major surface opposing the first major surface and at least one transistor cell formed in the semiconductor substrate. The transistor cell comprises a fin comprising an upper surface, side walls and a length. The length of the fin comprises a source region, a body region and a drift zone, wherein the body region extends between the source region and the drift zone. The transistor cell further comprises a gate arranged on the upper surface and side walls of the fin. A source pad is located on the first major surface and a drain pad is located on the second major surface of the semiconductor substrate.

According to an embodiment, a method of fabricating a vertical transistor device is provided. The method comprises forming a body region comprising a second conductivity type in a first major surface of a semiconductor substrate comprising a first conductivity type that opposes the second conductivity type, forming a source region in the body region and a drift zone in the first major surface adjacent the body region, forming a plurality of trenches in the first major surface, and thus forming a plurality of fins, one fin being defined by neighbouring ones of the trenches, wherein the trenches each have a length and extend from the source region though the body region to the drift zone such that each fin comprises a source region, a body region and a drift zone along its length, forming a gate dielectric over the fins and trenches, forming a gate metal over the gate dielectric or a polysilicon gate over the gate dielectric, forming a first metallization structure on the first major surface and forming a source pad that is electrically connected to the source regions and a gate pad that is electrically connected to the gate and forming a second metallization on the second major surface of the substrate that provides a drain pad.

According to an embodiment, a method of fabricating a vertical transistor device is provided. The method comprises forming a body region comprising a second conductivity type in a first major surface of a semiconductor substrate comprising a first conductivity type that opposes the second conductivity type and comprising a drift region, forming a plurality of trenches in the first major surface, thus forming a plurality of fins, one fin being defined by neighbouring ones of the trenches; wherein each trench has a length and extends from the source region though the body region into the drift region such that each fin comprises a body region and a drift region along its length, forming a gate dielectric over the fins and trenches, forming a gate metal over the gate dielectric or a polysilicon gate over the gate dielectric, forming a contact trench that extends between the body region and the drift region and perpendicularly to the length of the trenches, forming a source region in the body region by implanting dopants of a first conductivity type into a first side wall of the contact trench, forming a drift zone adjacent the body region by implanting dopants of a first conductivity type into a second side wall of the trench that opposes the first side wall, forming a first metallization structure on the first major surface and forming a source pad that is electrically connected to the source regions and a gate pad that is electrically connected to the gate and forming a second metallization on the second major surface of the substrate that provides a drain pad.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

FIG. 1A to FIG. 1C illustrate a transistor device according to an embodiment.

FIG. 2A to FIG. 2D illustrate a transistor device with a charge compensation structure according to an embodiment.

FIG. 3A and FIG. 3B illustrate a transistor device with a charge compensation structure according to an embodiment.

FIG. 4A and FIG. 4B illustrate a transistor device according to an embodiment.

FIG. 5A and FIG. 5B illustrate a transistor device according to an embodiment.

FIG. 6A to FIG. 6F illustrate a method for fabricating a transistor device according to an embodiment.

FIG. 7A to FIG. 7F illustrate a method for fabricating a transistor device according to an embodiment.

### DETAILED DESCRIPTION

In the following detailed description, reference is made to the accompanying drawings, which form a part hereof, and in which is shown by way of illustration specific embodiments. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto”another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

The Figures illustrate relative doping concentrations by indicating “−” or “+” next to the doping type “n” or “p”. For example, “n⁻” means a doping concentration which is lower than the doping concentration of an “n”-doping region while an “n⁺”-doping region has a higher doping concentration than an “n”-doping region. Doping regions of the same relative doping concentration do not necessarily have the same absolute doping concentration. For example, two different “n”-doping regions may have the same or different absolute doping concentrations.

In some embodiments, the vertical transistor device is a MOSFET (Metal Oxide Semiconductor Field Effect Transistor) device.

The present disclosure proposes a fin-based transistor device which is suitable for power applications (such as with a vertical current flow from one major surface of the transistor device to an opposing surface of the transistor device). In the fin-based transistor device, a three-dimensional body/channel fin is formed which is wrapped by a gate dielectric and gate-material on e.g. three sides of the fin. This arrangement enables a reduction of the on-resistance of the device by way of the pitch and depth of the fin structure. The concept aims to increase the possible channel width (not length) per area in order to maximize the channel cross-section and therefore further decrease the on-resistance. The source pad and drain pad of the transistor device are located on opposing major surfaces. At least a portion of the channel path of the transistor device extends vertically, that is in the direction between the opposing major surfaces of the transistor device so that the transistor device is a vertical transistor device. In some embodiments, another portion of the channel path is lateral as a highly doped drift zone extends to the first major surface and located on the opposing lateral side of the body region from the source region. The channel path of the transistor device comprises the channel which is formed next to the gate and the drift path which is formed in the drift region. The channel can be considered to be lateral as it extends substantially parallel to the first major surface and the drift path can be considered to be vertical as it extends substantially perpendicular to the first major surface.

In an embodiment, a combination of a trench field-plate with the fin structure is proposed. In some embodiments, the transistor device comprises a plurality of stripe-like trenches, each comprising stripe-like field plates. A mesa is located between neighbouring ones of the trenches. A fin-structure is formed, for example etched, into the mesa. The fin structure can be formed by etching a plurality of shallower trenches into the mesa so that a fin is formed between neighbouring ones of these shallower trenches. The length of the fin extends perpendicularly to the direction of the field-plate trenches.

The field plate may be directly contacted to the source terminal. This is desirable for applications that require a low output resistance (R_{OSS}). For applications where a low R_{OSS} can lead to issues with e.g. overshoots, engineering of the R_{OSS} may be possible by recessing the field plate and contacting it via a field plate bus. In other examples, the field plate may be connected to the gate terminal.

According to an embodiment a drift zone is formed at the opposing end of the fin from the source region. This arrangement may provide the gate dielectric with a better shielding against the drain potential.

A method for fabricating a vertical transistor device with a fin structure which is suitable for power applications is provided that is suitable for shallow fins. The source region is formed via a masked implant and diffusion after the body implant. On the side of the trench opposing the source region, the source implant can also be utilized to achieve an n or n+ region, called a drift zone herein, in order to improve the conduction in this narrow region. After the source implant the fins are etched. The gate oxide is deposited. e.g. by thermal oxidation, or by atomic layer deposition, in order to keep the temperature budget as low as possible and avoid further diffusion of the source. The gate electrode is then formed by metal deposition and structuring. If the metal gate is very thin, optionally the valleys may be filled with e.g. a dielectric prior to the structuring, in order to smoothen the topography for the lithography progress. Then the inter layer dielectric, the contact hole etch and the contact metallization is performed.

In case of deeper fins, the formation of the source region might not be sufficiently accurate if performed via implants from the top of the mesa. For deeper fins, the following process flow is proposed. In this second method, the fins are etched after the body implantation, followed by the gate dielectric and gate electrode deposition. Afterwards, the field dielectric is etched approximately to the depth of the fin. This allows the side-walls of the mesa to be implanted to form the source region and the drift zone on the opposing sides of the trench. Depending on the width of the drift zone next to the trench, this doped region might not reach the body region. Finally, the inter-layer dielectric, the contact hole etch and the contact metallization is carried out.

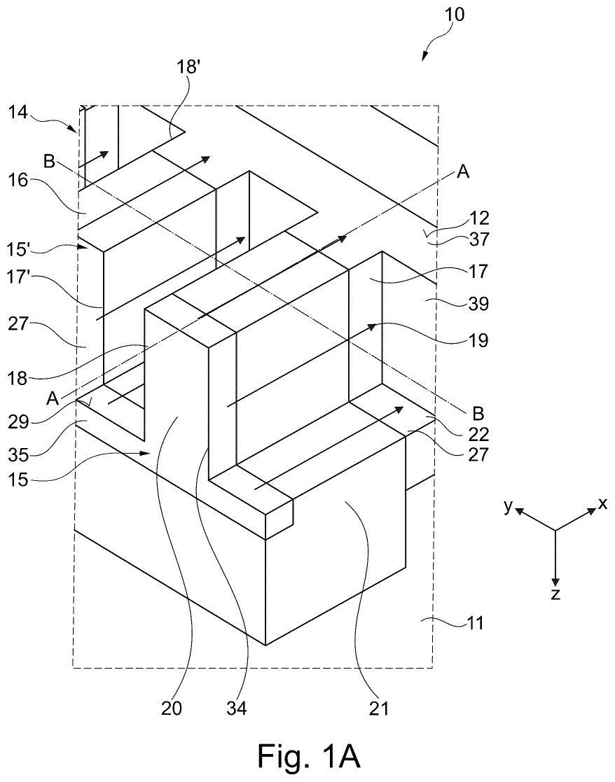

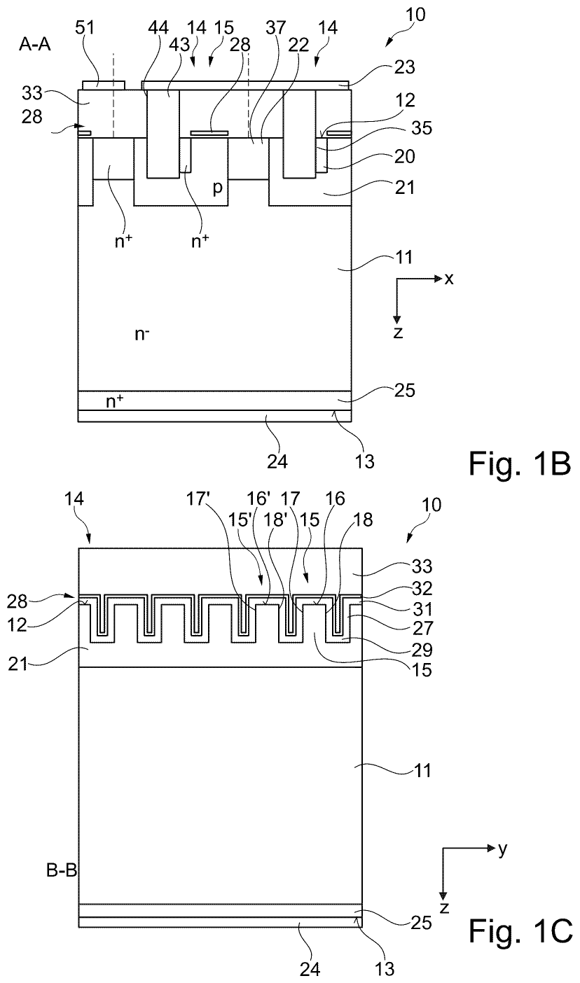

FIGS. 1A to 1C illustrate views of a vertical transistor device 10. FIG. 1A illustrates a perspective view, FIG. 1B illustrates a cross-sectional view along the line A-A shown in FIG. 1A and FIG. 1C illustrates a cross-sectional view along the line B-B shown in FIG. 1A.

The vertical transistor device 10 comprises a semiconductor substrate 11 having a first major surface 12 and a second major surface 13 which opposes the first major surface 12. The vertical transistor device 10 also comprises at least one transistor cell 14 which is formed in the semiconductor substrate 11. The transistor cell 14 comprises at least one fin 15 which comprises an upper surface 16, opposing sidewalls 17, 18 and a length which is illustrated in FIG. 1A by the arrow 19. The fin 15 comprises a substantially rectangular parallelepiped shape and is formed from the material of the semiconductor substrate 11. The fin 15 comprises a source region 20, a body region 21 and a drift zone 22 that are located along its length 19, whereby the body region 21 is arranged, and extends, between the source region 20 and the drift zone 22.

The portion of the semiconductor substrate 11 that is located under the fin 15 provides the drift region of the transistor device 10 and comprises a first conductivity type, for example n-type. The source region 20 also comprises the first conductivity type and is more highly doped than the semiconductor substrate 11. The body region 19 comprises a second conductivity type which opposes the first conductivity type and the drift zone 22 comprises the first conductivity type. The drift zone 22 may be more highly doped than the semiconductor substrate 11. If first conductivity type is n-type, the second conductivity type is p-type.

The upper surface 16 of the fin 15 may be formed from the first major surface 12. The source region 20, the body region 19 and the drift zone 22 are formed, for example by implantation of suitable dopants, at the first major surface 12 of the semiconductor substrate 11.

FIG. 1A illustrates only the fin 15 formed in the semiconductor substrate 11. FIGS. 1B and 1C further illustrate the gate 28 formed on the fin 15 and the metallization structure including an electrically insulating layer 33 that is formed on the gate 28 and in FIG. 1B also a source pad 23 and a gate pad 51 formed on the electrically insulating layer 33. The source pad 23 is arranged on the electrically insulating layer 33 located on first major surface 12 and a drain pad 24 is arranged on the second major surface 13. The source pad 23 of the first major surface 12 is electrically connected to the source region 20. A drain region 25 comprising the first conductivity type is formed at the second major surface 13. In some examples, the drain region 25 may be more highly doped than the semiconductor substrate 11. In other examples, the drain region 25 may have a same or similar doping as the semiconductor substrate 11. A drain pad 24 is located on the second major surface 13 and is in electrical contact with the drain region 25. The transistor cell 14 has a drift path comprising a vertical component since the source region 20 and body region 22 are formed at the first major surface 12 and the drain region 25 and drain pad 24 are arranged at the second major surface 13.

The semiconductor substrate 11 may comprise silicon and may be formed of monocrystalline silicon or an epitaxial silicon layer. The epitaxial silicon layer may be formed on a base substrate. The semiconductor substrate 11 may be known as an epi layer in this embodiment.

A fin 15 may be formed by forming two trenches 27 in in the first major surface 12 such that a fin 15 is formed between two neighbouring trenches 27. The sidewalls 17, 18 of the fin 15 also provide the side walls of trenches 27. The upper surface 16 of the fin 15 is provided by a portion of the first major surface 12 of the semiconductor substrate 11. The trenches 27 may have substantially rectangular parallelepiped shape and may be arranged substantially parallel to one another such that the width of each of the fin 15 formed between neighbouring ones of the trenches 27 is substantially uniform along its length 19. The upper surface 16 of the fin 15 is formed from a portion of the first major surface 12 and is therefore coplanar with the first major surface 12 of the semiconductor substrate 11.

Alternatively, the fins 15 may protrude from the first major surface 12 of the semiconductor substrate such that the upper surface 16 of the fins 15 lies in a different plane from the first major surface.

In some embodiments, the transistor cell 14 comprises a plurality of fins 15 which are arranged in a column and extend substantially parallel to one another. In other words, the lengths 19 of the fin 15 extends parallel substantially parallel to one another. Thus, one trench 27 having a base 29 is located between the sidewalls 17, 18 of neighbouring ones of the plurality of fins 15, whereby the base extends between the side walls 17, 18 of the neighbouring ones of the plurality of fins 15. The trench 27 can also be considered as a valley formed between neighbouring ones of the fins 15. The base 29 of the trench 27 is formed by a portion of the body region 21 as well as a portion of the source region 20 and the drift zone 22. The sidewalls 17, 18 and the upper surface 16 of the fin 15 are formed of the source region 20 body region 21 and the drift zone 22.

Referring to FIGS. 1B to 1C, the transistor cell 14 comprises a gate 28 which is arranged on the upper surface 16 and opposing sidewalls 17, 18 of the fin 15. The gate 28 extends over the side wall 17, upper surface 16 and sidewall 18 of the fin 15 over the base 29 of the trench 27 and up the sidewall 17′ and upper surface 16′ of the adjacent fin 15′ and so on. This arrangement of the gate 28 can be considered to provide a folded gate as is depicted in the cross-sectional view of FIG. 1C along the line B-B shown in FIG. 1A. FIG. 1C illustrates a cross-sectional view along the line B-B which extends substantially perpendicularly to the length of the fin 15. FIG. 1B illustrates a cross-sectional view along the through the length of the fin 15 along the line A-A shown in FIG. 1A.

The folded structure of the gate 28 can be seen in the cross-sectional view of FIG. 1C. This provision of the fins 15 formed between the trenches 27 formed in the first major surface 12 of the semiconductor substrate 11 has may lead to an increase of the width of the gate 28 without requiring an increase in the lateral area of the semiconductor substrate 11 in order to provide this increase in gate width. An increase of the width of the gate 28 may lead to an increase of the channel width.

In some embodiments, the gate 28 comprises a gate dielectric 31 and a gate metal layer 32 arranged on the gate dielectric 31. The gate dielectric 31 and the gate metal 32 extend over the sidewalls 17, 18 and top surface 16 of the fins 15 as well as the base 29 of the trenches 27 in order to form the folded gate structure as can be seen in the cross-sectional view of FIG. 1C. In some embodiments, the thickness of the gate dielectric 31 and gate metal 32 is such that the central portion of the trenches remains unoccupied by the gate dielectric 31 and gate metal 32. In some embodiments, the unoccupied central portion is filled with another dielectric 33 in order to provide increased mechanical stability and a smooth surface onto which further layers of the redistribution structure may be deposited. In some embodiments, the gate meal 32 fills the central portion of the trench 27 that is unoccupied by the gate dielectric 31.

In another embodiment, the gate 28 comprises a gate dielectric 31 and a polysilicon layer 32 arranged on the gate dielectric 31. The gate dielectric 31 and the polysilicon layer 32 are located on the base 29 of the trench 27, the sidewalls 17, 18 and the upper surface 16 of the fins 15. In an embodiment, the gate dielectric 31 and the polysilicon layer 32 have a thickness such that the central portion of the trench 27 remains unfilled and the polysilicon layer surrounds a gap. In an alternative embodiment, the polysilicon layer 32 substantially fills the centre portion of the trenches 27.

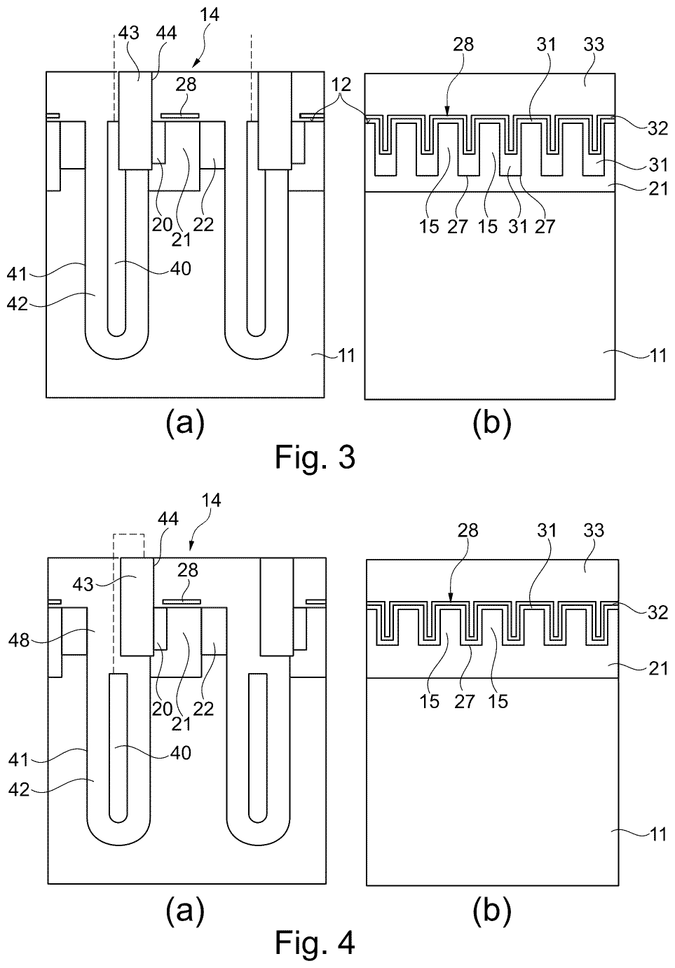

The thickness of the gate dielectric 31 over the base 29 of the trench 27, the sidewalls 17, 18 and upper surface 16 of the fin 15 may be substantially uniform as in the embodiment illustrated in FIG. 1C. In other embodiments, see for example FIGS. 3A and 3B, the thickness of the gate dielectric 31 may be greater on the base 29 of the trench 27 than on the sidewalls 17, 18 and upper surface 16 of the fin 15. This embodiment may be used to reduce short channel effects, e.g. due to block leakage paths.

In embodiments in which the transistor cell 14 comprises a plurality of fins 15, each having a source region 20, the source regions 20 of the plurality of fins 20 may be joined at a first end 34 of the fins 15 by a source bus 35 which is formed of the material of the semiconductor substrate 11 and which extends between the sidewalls 17, 18 of neighbouring fins 15, 15′. The source bus 35 comprises the first conductivity type and may also be more highly doped than the semiconductor substrate 11. Thus, the source regions 20 of the individual fins 15 are electrically connected in parallel within one transistor cell 14 by the source bus portion 35.

Similarly, the drift zones 22 of the plurality of fins 15 may connected together by a bus portion 37 formed of the material of the semiconductor substrate 11 that extends between the fins 15 at a second end 36 of the fins 15 that opposes the first end 34. The bus portion 37 may be more highly doped than the semiconductor substrate 11. The source bus portion 35 and the bus portion 37 may form the opposing short sidewalls 38, 39, respectively, of the trench 27 in order to form a rectangular parallelepiped trench 27. The source bus portion 35 and the bus portion 37 may extend substantially perpendicularly to the length 19 of the individual fins 15. The gate 28 has a strip-like form and extends substantially perpendicularly to the length of the plurality of fins 15 and substantially parallel to the length of the source bus 35 and bus portion 37.

In some embodiments, the source region 20 is formed in the body region 21 such that the body region 21 extends under the source region 20. The source region 20 is spaced apart from the drift region 11 provided by the semiconductor substrate 11 by the body region 21. The drift zone 22 is, in contrast, in contact with the drift region and is also in contact with the body region 21.

FIG. 1B also illustrates a contact 43 to the source region 20 and body region 21. The contact 43 is formed in the first major surface 12 and has the form of an elongate stripe which extends through the source bus 35. FIGS. 1B and 1C show the opening 44 in which the electrically conductive material for the contact 43 will be inserted.

The transistor device 10 may comprise a plurality of transistor cells 14 according to any one of the embodiments described herein, which are electrically coupled in parallel. Typically, the plurality of transistor cells 14 of a transistor device 10 have the same structure. For example, the source bus 35 of each of the transistor cells 14 may be electrically connected to a common source pad 23. The folded gate 28 of each of the transistor cells 14 may be allegedly connected to a gate pad 51, for example by means of a gate runner, which cannot be seen in the cross-sectional view of FIG. 1B. The gate runner may extend perpendicularly to the source bus 35. The gate pad 51 may be arranged on the first major surface 12. The drain region 25 and drain pad 24 may extend over substantially the entire second major surface 13 and a single drain region 25 provide the drain region 25 for each of the transistor cells 14 and fins 15.

In other non-illustrated embodiments, the gate pad is arranged on the second major surface 13. The gate pad on the second major surface 13 may be electrically connected to a gate runner on the first major surface 12 which is electrically connected to each of the folded gates 28 of the transistor cells 14. The gate pad on the second major surface 13 may be electrically connected to the gate runner on the first major surface 12 by a through contact or sinker structure which extends through the entire thickness of the semiconductor substrate 11 and which is electrically insulated from the semiconductor substrate 11. The position of the gate pad on either the first major surface 12 or the second major surface 13 may be selected depending on the packaging requirements of the semiconductor device 10.

Using the cartesian coordinate system, the transistor cells 14 may be arranged in a row so that the length of the fins 15 of neighbouring cells 14 are aligned with one another in the x direction. The alternate trenches 27 and fins 14 within one cell 14 are arranged in a column extending in the Y direction.

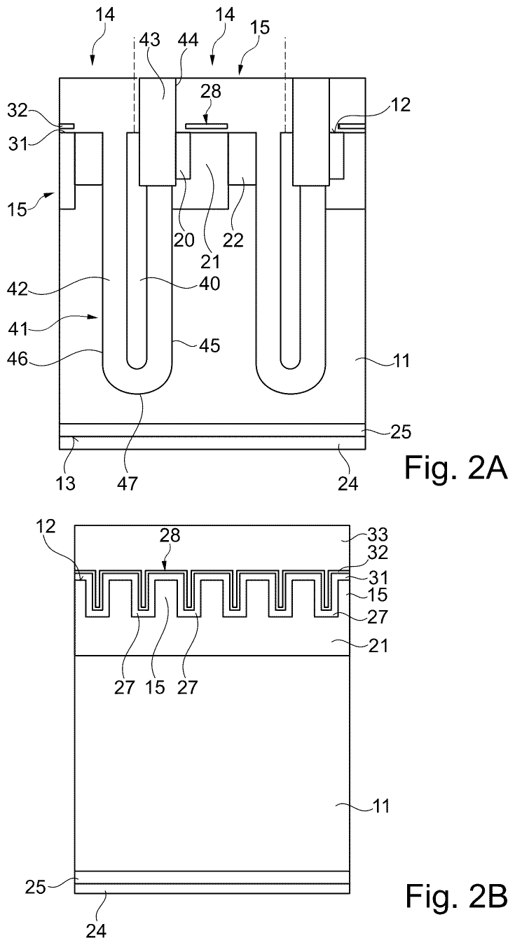

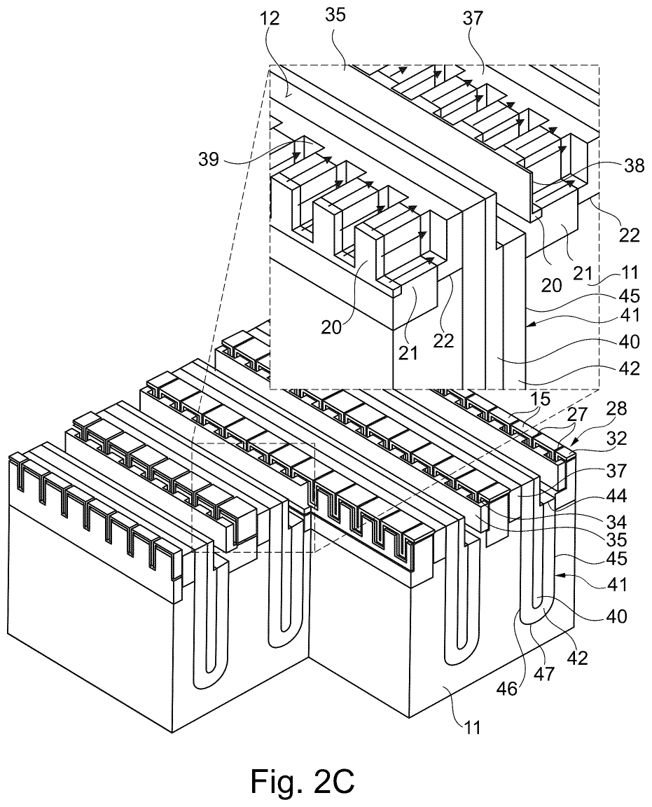

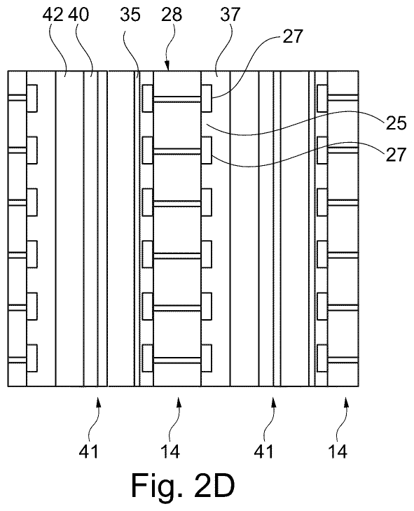

In some embodiments, the transistor device 10 further comprises a charge compensation structure. FIGS. 2A to 2D illustrate an embodiment, in which the charge compensation structure is formed by a field plate 40. Each transistor cell 14 includes a field plate 40 which is located in a trench 41 that is formed in the first major surface 12. FIG. 2A illustrates a cross-sectional view along the line A-A and along the length of the fin 15, FIG. 2B illustrates a cross-sectional view along the line B-B and across the width of the fin 15, FIG. 2C illustrates a perspective view, and FIG. 2D illustrates a top view of the transistor device 10.

As can be seen in the perspective view of FIG. 2C, the trench 41 has an elongate stripe shape having a length which extends parallel to the source bus 37 and perpendicular to the length 19 of the fins 15 of one transistor cell 14. The trench 41 comprises opposing sidewalls 45, 46 and a base 47 which are covered by the dielectric material 42. The field plate 40 fills the remainder of the trench 41 and also has a strip shape having a length which extends parallel to the source bus 37 and perpendicular to the length 19 of the fins 15 of one transistor cell 14. The field plate 40 may extend to the first major surface 12.

The field plate 40 is formed of electrically conductive material, for example polysilicon. The dielectric material 42 may provide a field dielectric and may be formed of an oxide, such as silicon dioxide. The field dielectric 42 may also comprise two or more sublayers which may have differing compositions, such as silicon nitride silicon oxide or may comprise oxide formed by different processing methods, for example silicon dioxide formed by thermal processing and are deposited layer silicon dioxide layer, for example formed using a TEOS (Tetra Ethyl Ortho Silicate) process.

The trench 41 is located between the source bus 35 of one transistor cell 14 and the drift zone 22 of the neighbouring transistor cell 14'. An opening 44 for a contact 43 is located between the field plate 40 and the source bus portion 35. The opening 44 has a width and a depth such that the base of the opening 44 is formed by a portion of the body region 22, the field dielectric 42 and the field plate 40. The opening 44 has a width such that a first side wall is formed by the source bus portion 37, the opening extends across the thickness of the dielectric material 42 arranged on a first side wall 45 of the trench 41 and an opposing second side wall is formed by a portion of the field plate 40. The contact 43 is in direct contact with the field plate 40 and with the source region 20 and body region 21.

In the perspective view of FIG. 2C and the top view of FIG. 2D, the opening 44 for the contact 43 has not been filled with conductive material. In the cross-sectional view of FIG. 2A, this opening 44 has been field with electrically conductive material to form the contact 43. For example, the contact 43 may be formed of a metal such as tungsten. The contact 43 may also be formed of polysilicon and/or may comprise two or more sublayers of differing composition.

As can be seen from the cross-sectional view of FIG. 2B along the width of a plurality of the fins 15 of a single cell 14, the structure of the folded gate 28 is same as that of the embodiment of FIGS. 1A to 1C which does not include a charge compensation structure.

FIGS. 3A and 3B illustrate a transistor device 10 according to an embodiment which differs from that illustrated in FIGS. 2A to 2D in form of the gate dielectric 31. FIG. 3A illustrates a cross-sectional view along the length of the fins 15 and FIG. 3B illustrates a cross-sectional view across the width of the fins 15. As can be seen in the cross-sectional view of FIG. 3B, the gate dielectric 31, which is located on the base 29 and sidewalls 17, 18 of the trenches 27 and upper surface 16 of the fins 15 has a greater thickness on the base 29 of the trenches 27 compared to its thickness on the upper surface 16 of the fins 15 and on the upper portion of the sidewalls 17, 18 of the fins 15. The gate metal 32 is located on the gate dielectric 31 and has a smaller area compared to that of the embodiments illustrated in FIGS. 1A-1C and 2A-2D since the lower part of the trenches 27 is entirely filled by the gate dielectric 31 to a greater depth. Alternatively, to retain the area of the gate metal 32 whilst increasing the thickness of the gate dielectric 31 on the base of the trench 27, the depth of the trench 27 may be increased.

In the embodiments illustrated in FIGS. 1A-1C and 2A-2D, the thickness of the gate dielectric 31 on the base 29 of the trenches 27 and the sidewalls, 17, 18 and upper surface 16 of the fin 15 is substantially uniform.

In the embodiments illustrated in FIGS. 2A-2D and 3A-3B, the field plate 40 is in direct contact with the contact 43 which is also in direct contact with the source region 20 and body region 21.

FIGS. 4A and 4B illustrate a transistor device 10 with transistor cells 14 comprising a plurality of fins 15 and a charge compensation structure in the form of a field plate 40. The transistor device 10 of this embodiment differs form that described with reference to FIGS. 3A and 3B in the arrangement of the field plate 40 within the trench 41.

FIG. 4A illustrates a cross-sectional view along the length of the fins 15 and FIG. 4B a cross-sectional view across the width of the fins 15 of one of the transistor cells 14. In this embodiment, the field plate 40 is located towards the bottom of the trench 41 and is covered at the upper end of the trench 41 by dielectric material 48. The field plate 40 within the trench 41 is spaced apart and electrically insulated from the body region 21 and source region 20, which form the upper portion of a first sidewall 45 of the trench 41 and is also spaced apart and electrically insulated from the drift zone 22 which forms the upper portion of the opposing second sidewall 46 of the trench 41 by the field dielectric 42. The contact 43 extends into the first major surface 12 such that it is in contact with the source region 20 and the body region 21 and also extends over a portion of the trench 41. The contact 43 is, however, spaced apart from the underlying field plate 40 by the intervening portion of the field dielectric material 48. The field plate 40 within the trench 41 is electrically connected to source potential in a plane which is not shown in the cross-sectional views, for example, at the end of the elongate trenches 41. At this position, a contact can be made from the first major surface 12 down to the field plate 40 in order to electrically connect field plate 40 to the electrical redistribution structure for the source, for example, a metal source bus or source pad formed on the first major surface 12 which electrically connects the contacts of the transistor cells 14 to one another. The metal source bus formed on the first major surface 12 may be laterally spaced apart from the transistor cell 14 and may also be laterally spaced apart from the source regions 20 within the transistor cells 14.

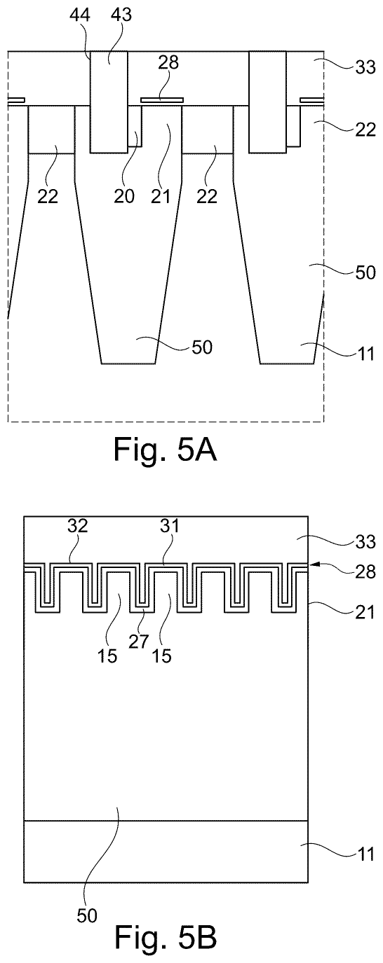

FIGS. 5A and 5B illustrate a transistor device 10 comprising a plurality of the transistor cells 14, each having a plurality of fins 15 and a charge compensation structure according to another embodiment. FIG. 5A illustrates a cross-sectional view across the width of the fins 15 and FIG. 5B a cross-sectional view along the length of the fins 15.

In this embodiment, the transistor device 10 comprises a charge compensation structure in the form of a doped region 50 in place of the trench 41 with the field plate 40. The region 50 is doped with the second conductivity type. The remainder of the structure of the fins 15, gate 28 etc. is the same as illustrated in and described with reference to FIGS. 1A to 1C. The doped region 50 extends from the first major surface 12 into the semiconductor substrate 11. The doped region 50 extends from the body region 21 towards the second major surface 13 of the semiconductor substrate 11 and forms an elongated column or wall of material that is doped with the second conductivity type. The base of the doped region 50 is spaced apart from the drain region 25 by a portion of the drift region provided by the semiconductor substrate 11. The doped region 50 has a stripe-shaped having a length which is greater than its width, whereby the length and the width lie in the plane that is parallel with the first major surface 12 of the semiconductor substrate 11. The length of the doped region 50 extends perpendicularly to the length of the fin 15. The width of the top of the doped region 50 corresponds to the width of the body region 20. The doped region can be considered to be a vertical extension of the body region 20. The doped region 50 may have a tapered form in the plane extending along the length of the fin 15 such that the base of the doped region 50 is narrower than the body region 21 at the first major surface 12. A plurality of columns of alternate doping are formed in the drift region of the vertical transistor device 10 and provide a superjunction charge compensation structure.

In examples, the source region 20 may be located towards the lateral centre of the doped region 50. The gate 28 is formed above one edge region of the body region 20 and is laterally adjacent to the source region 20. The contact 43 extends from the first major surface 12 into the doped region 50 and overlaps with the source region 20 and the body region 21. The contact 43 may have an elongate stripe-like structure and extend along all or the majority of the length of the doped column 50.

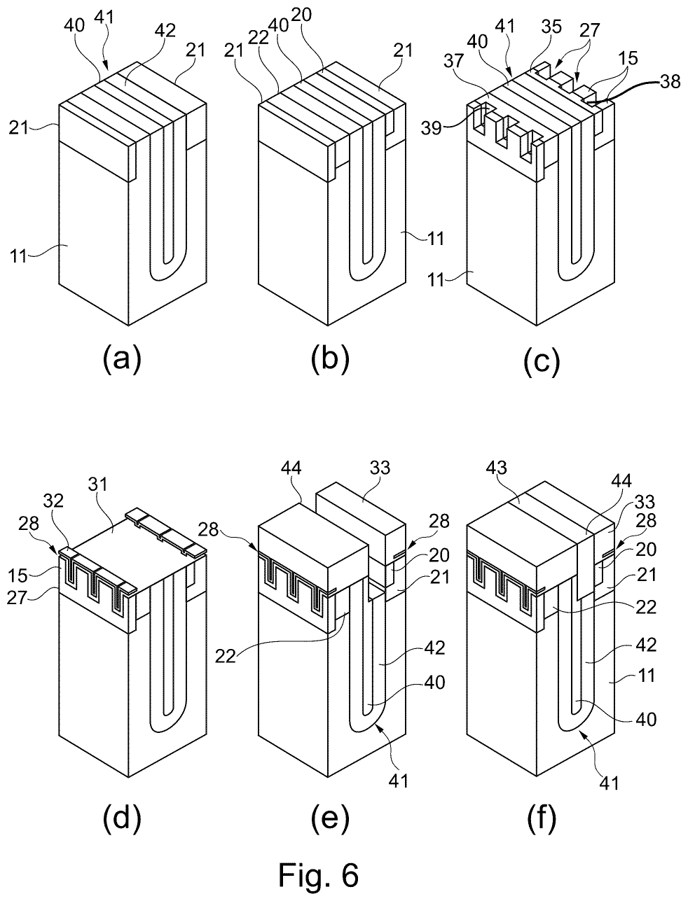

FIGS. 6A to 6F illustrate a method for fabricating a transistor device. The method may be used to fabricate the transistor device illustrated in FIGS. 2A to 2D. The semiconductor the transistor device 10 comprises a plurality of transistor cells 14 each of which have substantially the same design. The method will be described with reference to one of these transistor cells 14. However, the method is typically carried out for each of the plurality of transistor cells 14 of the transistor device 10 during the same processes.

A semiconductor substrate 11 of the first conductivity type with a first major surface 12 and an opposing second major surface 13 is provided. The semiconductor substrate 11 may comprise silicon, e.g. be formed of an epitaxial silicon layer. In this embodiment, the transistor cell 14 comprises a charge compensation structure in the form of a field plate 40. Elongate trenches 41 are formed in first major surface 12, each trench 41 each having a base 47 and opposing sidewalls 45, 46 to form an elongate strip-like trench 41. The first and second sidewalls 45, 46 and the base 47 of the trench 41 are covered by dielectric material 42 and then conductive material inserted into the remainder of the trench 41 to form the field plate 40. A planarization process may then be carried out, for example by chemical mechanical polishing (CMP). The body region 21 is formed in the first major surface 12 such that it adjoins the upper portion of the first sidewall 45 and such that the opposing second sidewall 46 is formed of the material of the semiconductor substrate 11. The body region 21 may be formed by implanting dopants of the second conductivity type into the semiconductor substrate 11. FIG. 6A shows the device after the body region 21 is formed.

Referring to FIG. 6B, a source region 20 is then formed in the body region 21 and is located such that it adjoins the upper portion of the first sidewall 45 of the trench 41. The source region 21 may be formed by implanting dopants of the first conductivity type into the first major surface 12. In some embodiments, the drift zone 22, which is more highly doped than the substrate 11, is also formed which forms a portion of the opposing second sidewall 46 of the trench 41. The drift zone 22 may also be formed by implantation of the dopants of the first conductivity type into the first major surface 12, for example at the same time as forming the source region 20.

Referring to FIG. 6C, a plurality of trenches 27 are formed in the first major surface 12 which are positioned such that they have an end face formed by the source region 20 and an opposing end face formed by the drift zone 22 and sidewalls 17, 18 which are formed by the body region 21 and source region 20 and drift zone 22. The trenches 27 are arranged in a column and spaced apart from one another such that a rectangular parallelepiped fin 15 is formed between adjacent ones of the trenches 27. The trenches 27 may be substantially rectangular in top view and the fins 15 may also have a substantially rectangular form in top view. The fins 15 and the trenches 27 have a length which extends perpendicularly to the length of the trench 41 and field plate 40. The plurality of trenches 27 and the fins 15 are arranged alternately in the column in the y direction which corresponds to the longest dimension (length) of the trench 41. The trenches 27 are formed between neighbouring ones of the trenches 41 and have a length that extends perpendicularly to the length of the trenches 41.

Referring to FIG. 6D, a gate structure 28 is then formed which extends over the fins 15 and trenches 27. A dielectric material 31 is deposited over the first major surface 12 which extends over the sidewalls 17, 18 and base 29 of the trenches 27 and the upper surface 16 of the fins 15 and forms the gate dielectric. A conductive material 32, for example a gate metal, is deposited which extends over the sidewalls 17, 18 and base 29 of the trenches 27 and the upper surface 16 of the fins 15. Thus, a folded metal gate 28 is formed. The gate metal 32 has a lateral extent such that it is positioned above the body region 21 formed in the fin 15 and overlaps the edge of the source region 20 and the drift zone 22 formed in the fin 15. In some embodiments, the gate metal 32 may extend over the peripheral edge of the source region 23 and of the drift zone 22.

Referring to FIG. 6E, a further interlayer dielectric 33 is formed on the first major surface 12 that covers the gate metal 32 and the trench 41. An opening 44 is formed through the interlayer dielectric 33 which exposes the upper portion of the field plate 40. The opening 44 has a lateral extent such that it extends from the field plate 40 over the field dielectric 42 towards the body region 21. The lower surface of the opening 44 is formed at the periphery by the field plate 40 and the body zone 21. The opening 44 has an elongate structure having a length which extends parallel to the length of the trench 41.

Referring to FIG. 6F, conductive material is then inserted into the opening 44 to form a contact 43 which extends between the field plate 40 and the source region 20 and body zone 21 and electrically connects the field plate 40, source region 20 and body region 21 to source potential.

A first metallization structure is then applied to the first major surface. The first metallization structure includes a source pad 23 that is electrically connected to the contacts 43 and a gate pad 51 that is electrical connected to the gates 28. A second metallization is applied to the opposing second major surface 13 of the semiconductor substrate onto a drain region 25 hat is formed at the second major surface 13. The second metallization provides the drain pad 24.

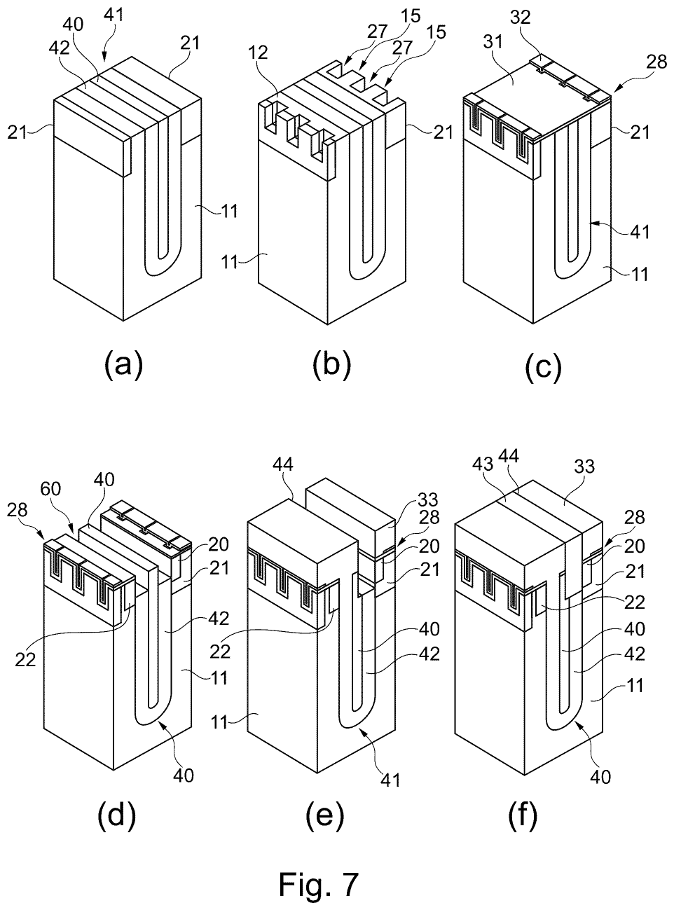

A method of fabricating the transistor device according to another embodiment now be described with reference to FIGS. 7A to 7F. This method may be used to fabricate the transistor device 10 described with reference to FIGS. 2A to 2D. The method may be used for fabricating transistor devices 10 in which the fins 15 are higher. In other words, the side walls 17, 18 of the fin 15 have a greater height so that the base 29 of the trenches 27 lies at a greater distance from the first major surface 12. In the method illustrated with reference to FIGS. 6A to 6F, the source region 20 and drift zone 22 are formed before the fabrication of the fins 15 and the gate 28. In contrast, the method described with reference to FIGS. 7A to 7F, the source region 20 and drift zone 22 are formed after the fabrication of the trenches 27 and fins 15 and after the fabrication of the gate 28.

Referring to FIG. 7A, a semiconductor substrate 11 of the first conductivity type is provided which has, for each transistor cell 14, an elongate trench 41 lined with field dielectric 42 and comprising a field plate 40. The body region 22, which forms the upper portion of the first sidewall 45 of the trench 41, has been formed by implanting dopants of the second conductivity type.

Referring to FIG. 7B, trenches 27 are then formed in the first major surface 12 each having a rectangular form in top view such that a rectangular protrusion, i.e. fin 15, is formed between adjoining ones of trenches 27. The trenches 27 are formed between neighbouring ones of the trenches 41 and have a length that extends perpendicularly to the length of the trenches 41 such that the first end face 38 is formed from the material of the body region 21 and the opposing end face 39 is positioned in the semiconductor substrate 11.

Referring to FIG. 7C, a dielectric layer 31 is formed on the first major surface 12 which covers the first major surface 12 including the field plate 40 and trench 41 and the body region 21. The dielectric layer 31 also lines the base 29 of the trenches 27 and covers the sidewalls 17, 18 and upper surface 16 of the fins 15 and provides the gate dielectric. A gate metal 32 is then deposited which onto the gate dielectric 31. The gate metal 32 is structured so as to form a folded stripe-like gate structure 28 that extends over the base 29 of the trench 27 and the sidewalls 17, 18 and upper surface 16 of the fins 15 to form a folded gate structure. The gate metal 32 has a width such that it is positioned above the body region 21 and slightly overlaps with the source region 20 and drift zone 22.

Referring to FIG. 7D, an opening 60 is formed above the trench 41 which exposes the field plate 40 and which removes the field dielectric 42 in the upper portion of the trench 41. The field dielectric 42 is selectively removed, e.g. by etching, from the upper portion of the trench 41 such that the upper portion of the field plate 40 is uncovered and protrudes from the remainder of the field dielectric 42. The depth of the opening 60 is less than the depth of the pn junction formed between the body region 21 and the underlying semiconductor substrate 11. The source region 20 and is then formed by implanting dopants of the first conductivity type into the exposed sidewall 45 of the trench 41 which adjoins the body region 21. The drift zone 22 is then formed by implanting dopants of the first conductivity type into the exposed opposing sidewall 46 of the trench 41 which is formed by material the semiconductor substrate 11.

Referring to FIG. 7E, a dielectric material 33 is deposited onto the first major surface 12 which covers the gate metal 32 and fills the opening 60 formed in the upper portion of the trench 41 and covers the field plate 40. Referring to FIG. 7F, an elongate opening 44 for a contact 43 is formed which extends between the field plate 40 and the source region 20 and body region 21. The opening 44 is then filled with conductive material to form the contact 43 as described in connection with FIGS. 6E and 6F. A first metallization structure is then applied to the first major surface. The first metallization structure includes a source pad that is electrically connected to the contacts 43 and a gate pad that is electrical connected to the gates 28. A second metallization is applied to the opposing second major surface 13 of the semiconductor substrate onto a drain region that is formed at the second major surface 13. The second metallization provides the drain pad.

To summarise, a transistor device 10 is provided in which each transistor cell comprises at least one fin 15 and a folded gate 28. The transistor device 10 has a reduced on-resistance arising from the increased channel width (not length) per area which increases the channel cross-section and decreases the on-resistance.

Although the present disclosure is not so limited, the following numbered examples demonstrate one or more aspects of the disclosure.

Example 1. A vertical transistor device, comprising: a semiconductor substrate comprising a first major surface and a second major surface opposing the first major surface; at least one transistor cell formed in the semiconductor substrate, wherein the transistor cell comprises a fin comprising an upper surface, side walls and a length, wherein the length of the fin comprises a source region, a body region and a drift zone, wherein the body region extends between the source region and the drift zone, and wherein the transistor cell comprises a gate arranged on the upper surface and side walls of the fin, wherein a source pad is located on the first major surface and a drain pad is located on the second major surface of the semiconductor substrate.

2. The vertical transistor device according to example 1, wherein the transistor cell has a channel path comprising a vertical component.

3. The vertical transistor device according to example 1 or example 2, wherein the fin is a protrusion formed of the material of the semiconductor substrate.

4. The vertical transistor device according to any one of examples 1 to 3, wherein the semiconductor substrate comprises silicon.

5. The vertical transistor device according to any one of examples 1 to 4, wherein the semiconductor substrate is formed of an epitaxial layer.

6. The vertical transistor device according to any one of examples 1 to 5, wherein the source pad is electrically connected to the source region and the drain pad is electrically connected to a drain region arranged at the second major surface of the semiconductor substrate.

7. The vertical transistor device according to any one of examples 1 to 6, wherein the first major surface forms the upper surface of the fin.

8. The vertical transistor device according to any one of examples 1 to 7, wherein the gate comprises a gate dielectric and a gate metal layer arranged on the gate dielectric, or the gate comprises a gate dielectric and a polysilicon layer arranged on the gate dielectric.

9. The vertical transistor device according to any one of examples 1 to 8, wherein the transistor cell comprises two trenches, each having a base and extending substantially parallel to one another such that a fin is located between the trenches, wherein the gate extends over the upper surface and side walls of the fin and the base of the trenches.

10. The vertical transistor device according to any one of examples 1 to 9, wherein the transistor cell comprises plurality of fins extending substantially parallel to one another such that a trench having a base is located between the sidewalls of neighbouring ones of the plurality of fins and a plurality of trenches is formed, wherein the gate extends over the upper surface and side walls of the plurality of fins and the base of the trenches.

11. The vertical transistor device according to any one of examples 9 to 10, wherein the gate extends over the upper surface and side walls of the plurality of fins and the base of the trenches to form a folded gate.

12. The vertical transistor device according to any one of examples 9 to 11, wherein the gate comprises a gate dielectric positioned on the upper surface and side walls of the fins and the base of the trenches and a gate metal layer arranged on the gate dielectric, or the gate comprises a gate dielectric positioned on the upper surface and side walls of the fins and the base of the trenches and a polysilicon layer arranged on the gate dielectric.

13. The vertical transistor device according to any one of examples 9 to 11, wherein the gate comprises a gate dielectric positioned on the upper surface and side walls of the fins and the base of the trenches and a polysilicon layer arranged on the gate dielectric and the polysilicon layer fills the trench formed between adjacent fins.

14. The vertical transistor device according to any one of examples 8 to 13, wherein the thickness of the gate dielectric on the base of the trench is greater than a thickness on the side walls and upper surface of the fin or the thickness of the gate dielectric on the base of the trench and the thickness on the side walls and upper surface of the fin is substantially uniform.

15. The vertical transistor device according to any one of examples 1 to 14, wherein the source regions of the plurality of fins are joined at a first end of the fins by a source bus portion that extends between the fins and that is formed from the material of the semiconductor substrate, and wherein the drift zone of the plurality of fins are joined at a second end of the fins by a bus portion that extends between the fins and that is formed from the material of the semiconductor substrate, wherein the second end opposes the first end.

16. The vertical transistor device according to example 15, wherein the source bus portion and the bus portion extend substantially perpendicularly to the length of the fins.

17. The vertical transistor device according to any one of examples 1 to 16, wherein the semiconductor substrate comprises a first conductivity type and provides a drift region, the source region comprises the first conductivity type, the body region comprises a second conductivity type opposing the first conductivity type and the drift zone comprises the first conductivity type, wherein the drift zone and the source region are more highly doped than the drift region.

18. The vertical transistor device according to any one of examples 1 to 17, wherein the source region, the body region and the drift zone are arranged at the first major surface.

19. The vertical transistor device according to any one of examples 1 to 18, further comprising a drain region arranged at the second major surface, wherein the drain region comprises the first conductivity type and is more highly doped than the drift region.

20. The vertical transistor device according to any one of examples 1 to 19, wherein the source region is formed in the body region and the drift zone is in contact with the drift region.

21. The vertical transistor device according to any one of examples 1 to 20, further comprising a charge compensation structure.

22. The vertical transistor device according to example 21, wherein the charge compensation structure comprises a field plate located in a field plate trench located in the first major surface.

23. The vertical transistor device according to example 22, wherein the field plate trench has a striped shape having a length a length that is greater than its width in a plane that lies parallel with the first major surface and the length of the field plate trench extends perpendicularly to the length of the fin.

24. The vertical transistor device according to example 23, wherein the length of the field plate trench extends parallel to the source bus portion and the bus portion.

25. The vertical transistor device according to example 23 or example 24, wherein the field plate trench is located between neighbouring transistor cells.

26. The vertical transistor device according to any one of examples 23 to 25, wherein the field plate is electrically connected to the source region and the body region by a contact that is positioned at least partially in the field plate trench.

27. The vertical transistor device according to example 26, wherein the contact is a strip-like contact that extends parallel to the field plate and between the field plate and the source bus.

28. The vertical transistor device according to example 27, wherein the contact extends from the field plate to the source region and body region that forms a section of a first side wall of the trench and wherein the drift zone of a neighbouring transistor cell forms a section of a second side wall of the trench that opposes the first side wall.

29. The vertical transistor device according to example 27, wherein the field plate is electrically isolated from the semiconductor substrate by a dielectric material lining the field plate trench and is spaced apart from the source region and drift zone forming the section of the first side wall of the field plate trench by dielectric material, wherein the field plate is electrically connected to the source region by a contact that extends to a source metallization that is located on the first major surface and laterally adjacent the at least one transistor cell.

30. The vertical transistor device according to example 21, wherein the charge compensation structure comprises a doped region that is doped with the second conductivity type that that extends from the body region towards the second major surface.

31. The vertical transistor device according to example 30, wherein the doped region has a striped shape with a length that is greater than its width in a plane that lies parallel with the first major surface and the length of the doped region extends perpendicularly to the length of the fin.

32. The vertical transistor device according to example 31, wherein the length of the doped region extends parallel to the source bus portion and the bus portion.

33. A method of fabricating a vertical transistor device, the method comprising: forming a body region comprising a second conductivity type in a first major surface of a semiconductor substrate comprising a first conductivity type that opposes the second conductivity type; forming a source region in the body region and a drift zone in the first major surface adjacent the body region; forming a plurality of trenches in the first major surface, and thus forming a plurality of fins, one fin being defined by neighbouring ones of the trenches, wherein the trenches each have a length and extend from the source region though the body region to the drift zone such that each fin comprises a source region, a body region and a drift zone along its length; forming a gate dielectric over the fins and trenches; forming a gate metal over the gate dielectric or a polysilicon gate over the gate dielectric; forming a first metallization structure on the first major surface and forming a source pad that is electrically connected to the source regions and a gate pad that is electrically connected to the gate; forming a second metallization on the second major surface of the substrate that provides a drain pad.

34. A method of fabricating a vertical transistor device, the method comprising: forming a body region comprising a second conductivity type in a first major surface of a semiconductor substrate comprising a first conductivity type that opposes the second conductivity type and comprising a drift region; forming a plurality of trenches in the first major surface, thus forming a plurality of fins, one fin being defined by neighbouring ones of the trenches; wherein each trench has a length and extends from the source region though the body region into the drift region such that each fin comprises a body region and a drift region along its length; forming a gate dielectric over the fins and trenches; forming a gate metal over the gate dielectric or a polysilicon gate over the gate dielectric, forming a contact trench that extends between the body region and the drift region and perpendicularly to the length of the trenches; forming a source region in the body region by implanting dopants of a first conductivity type into a first side wall of the contact trench; forming a drift zone adjacent the body region by implanting dopants of a first conductivity type into a second side wall of the trench that opposes the first side wall; forming a first metallization structure on the first major surface and forming a source pad that is electrically connected to the source regions and a gate pad that is electrically connected to the gate; forming a second metallization on the second major surface of the substrate that provides a drain pad.

35. The method according to example 33 or example 34, further comprising: forming at least one electrically insulating layer on the first major surface; forming a trench for a contact that extends into the source and body region at a position laterally adjacent to the fins, inserting conductive material into the trench.

36. The method according to any one of examples 33 to 35, further comprising: before forming the body region, forming a trench for a field plate, lining the trench with a dielectric material and inserting conductive material into the trench to form a field plate, wherein the body region is formed so as to form a first side wall of the trench and such that a second side wall of the trench opposing the first side wall is formed by the semiconductor substrate.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise. It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A vertical transistor device, comprising:
a semiconductor substrate comprising a first major surface and a second major surface opposing the first major surface;
at least one transistor cell formed in the semiconductor substrate, wherein the transistor cell comprises a fin comprising an upper surface and side walls, wherein the transistor cell further comprises a source region, a body region and a drift zone that are located along a length of the fin, wherein the body region extends between the source region and the drift zone, and wherein the transistor cell further comprises a gate arranged on the upper surface and the side walls of the fin; and
a source pad on the first major surface of the semiconductor substrate.

2. The vertical transistor device of claim 1, wherein the transistor cell further comprises two trenches, each having a base and extending substantially parallel to one another, wherein the fin is located between the two trenches, and wherein the gate extends over the upper surface and the side walls of the fin and the base of the two trenches.

3. The vertical transistor device of claim 1, wherein the gate comprises a gate dielectric and a gate metal layer arranged on the gate dielectric, or the gate comprises a gate dielectric and a polysilicon layer arranged on the gate dielectric.

4. The vertical transistor device of claim 3, wherein the transistor cell comprises a plurality of fins extending substantially parallel to one another such that a trench having a base is located between the sidewalls of each of neighbouring ones of the fins, and wherein the gate extends over the upper surface and the side walls of the fins and the base of the trenches.

5. The vertical transistor device of claim 3, wherein a thickness of the gate dielectric on the base of the trench is greater than a thickness of the gate dielectric on the side walls and the upper surface of the fin.

6. The vertical transistor device claim 4, wherein source regions of the fins are joined at a first end of the fins by a source bus portion that extends between the fins and is formed from a material of the semiconductor substrate, wherein drift zones of the fins are joined at a second end of the fins by a bus portion that extends between the fins and is formed from the material of the semiconductor substrate, and wherein the second end opposes the first end.

7. The vertical transistor device of claim 1, wherein the semiconductor substrate comprises a first conductivity type and provides a drift region, the source region comprises the first conductivity type, the body region comprises a second conductivity type opposing the first conductivity type and the drift zone comprises the first conductivity type, and wherein the drift zone and the source region are more highly doped than the drift region.

8. The vertical transistor device of claim 1, wherein the source region, the body region and the drift zone are arranged at the first major surface.

9. The vertical transistor device of claim 1, wherein the source region is formed in the body region and the drift zone is in contact with a drift region of the semiconductor substrate.

10. The vertical transistor device of claim 1, further comprising a charge compensation structure.

11. The vertical transistor device of claim 10, wherein the charge compensation structure comprises a field plate in a field plate trench located in the first major surface.

12. The vertical transistor device of claim 11, wherein the field plate trench has a striped shape having a width and a length that is greater than the width in a plane that lies parallel with the first major surface, and wherein the length of the field plate trench extends perpendicularly to a length of the fin.

13. The vertical transistor device of claim 11, wherein the field plate trench is located between neighbouring transistor cells.

14. The vertical transistor device of claim 11, wherein the field plate is electrically connected to the source region and the body region by a contact that is positioned at least partially in the field plate trench.

15. The vertical transistor device of claim 14, wherein the contact extends from the field plate to the source region and the body region which form a section of a first side wall of the trench, and wherein the drift zone of a neighbouring transistor cell forms a section of a second side wall of the field plate trench that opposes the first side wall.

16. The vertical transistor device of claim 14, wherein the field plate is electrically isolated from the semiconductor substrate by a dielectric material lining the field plate trench and is spaced apart from the source region and the body region forming the section of the first side wall of the field plate trench by dielectric material, and wherein the field plate is electrically connected to the source region by the contact that extends to a source metallization that is located on the first major surface and laterally adjacent the at least one transistor cell.

17. The vertical transistor device of claim 10, wherein the charge compensation structure comprises a doped region of the second conductivity type that extends from the body region towards the second major surface.

18. The vertical transistor device of claim 17, wherein the doped region has a striped shape with a width and a length that is greater than the width in a plane that lies parallel with the first major surface, and wherein the length of the doped region extends perpendicularly to a length of the fin.

19. A method of fabricating a vertical transistor device, the method comprising:
forming a body region comprising a second conductivity type in a first major surface of a semiconductor substrate comprising a first conductivity type that opposes the second conductivity type;
forming a source region in the body region and a drift zone in the first major surface adjacent the body region;
forming a plurality of trenches in the first major surface and that defines a plurality of fins, one fin being defined by neighbouring ones of the trenches, wherein the trenches each have a length and extend from the source region though the body region to the drift zone such that each fin comprises a source region, a body region and a drift zone along the fin length;
forming a gate dielectric over the fins and the trenches;
forming a gate metal over the gate dielectric or a polysilicon gate over the gate dielectric; and
forming a first metallization structure on the first major surface of the semiconductor substrate and that provides a source pad that is electrically connected to the source regions and a gate pad that is electrically connected to the gate.

20. The method of claim 19, further comprising:
forming at least one electrically insulating layer on the first major surface of the semiconductor substrate and that fills the additional trench;
forming a contact trench that extends into the source region and the body region at a position laterally adjacent to the fins; and
inserting conductive material into the contact trench to form a contact in the contact trench.

21. The method of claim 19, further comprising:
before forming the body region, forming a field plate trench in the semiconductor substrate;
lining the field plate trench with a dielectric material; and
inserting conductive material into the field plate trench to form a field plate,
wherein the body region forms a first side wall of the field plate trench,
wherein a second side wall of the field plate trench opposing the first side wall is formed by the semiconductor substrate.

22. A method of fabricating a vertical transistor device, the method comprising:
forming a body region comprising a second conductivity type in a first major surface of a semiconductor substrate comprising a first conductivity type that opposes the second conductivity type and comprising a drift region;
forming a plurality of trenches in the first major surface and that defines a plurality of fins, one fin being defined by neighbouring ones of the trenches, wherein each trench has a length and extends through the body region and into the drift region such that each fin comprises a body region;
forming a gate dielectric over the fins and the trenches;
forming a gate metal over the gate dielectric or a polysilicon gate over the gate dielectric;
forming an additional trench that extends between the body region and the drift region and perpendicularly to the length of the trenches;
forming a source region in the body region by implanting dopants of a first conductivity type into a first side wall of the additional trench;
forming a drift zone by implanting dopants of the first conductivity type into a second side wall of the additional trench that opposes the first side wall; and
forming a first metallization structure on the first major surface of the semiconductor substrate and that provides a source pad that is electrically connected to the source region and a gate pad that is electrically connected to the gate.

23. The method of claim 22, further comprising:
forming at least one electrically insulating layer on the first major surface of the semiconductor substrate and that fills the additional trench;
forming a contact trench that extends into the source region and the body region at a position laterally adjacent to the fins; and
inserting conductive material into the contact trench to form a contact in the contact trench.

24. The method of claim 22, further comprising:
before forming the body region, forming a field plate trench in the semiconductor substrate;
lining the field plate trench with a dielectric material; and
inserting conductive material into the field plate trench to form a field plate,
wherein the body region forms a first side wall of the field plate trench,
wherein a second side wall of the field plate trench opposing the first side wall is formed by the semiconductor substrate.
